(19) United States
(12) Patent Application Publication
(10) Pub. No.: US 2001/0017547 A1
(43) Pub. Date: Aug. 30, 2001

(54) Tape-like member transfer system

(76) Inventor: Mitsuhiro Furuta, Tokyo (JP)

Correspondence Address: FLYNN, THIEL, BOUTELL & TANIS, P.C., 2026 Rambling Road, Kalamazoo, MI, 49008-1699, US

(21) Appl. No.: 09/766,313

(22) Filed: Jan. 18, 2001

(30) Foreign Application Priority Data
Feb. 29, 2000 (JP) 2000-52776

(51) Int. Cl. G01R 27/02; B66F 1/00; B65G 1/00

(52) U.S. Cl. 324/604

(57) ABSTRACT

A tape-like member or TAB tape transfer system formed of a thin film tape is transferred without being flexible in the width direction thereof. A tape-like member transfer system comprises a TAB tape having conductive patterns formed thereon along the longitudinal direction and mounting semiconductor chips thereon, transfer roller pairs for transferring the TAB tape while putting it therebetween and a test device provided on the midway of transfer of the TAB tape, wherein the transfer roller pairs are arranged on both end sides of the TAB tape in the width direction, and when an amount of binding of the TAB tape which protrudes upward and substantially perpendicular to the transfer surface of the TAB tape is detected by a detection sensor while the TAB tape is transferred, axes of rotation of the driving rollers of the transfer roller pairs are inclined at a given angle by a control motor so as to apply right and left tensile forces to the TAB tape in the width direction so that the TAB tape is transferred without being bent.

### BACKGROUND OF THE INVENTION

1. Field of the Invention

The invention relates to a tape-like member transfer system for transferring a film-like member such as, e.g., a photographic film, a paper tape or the like.

2. Description of the Related Art

There is known a TAB tape (Tape Automated Bonding Tape, hereinafter referred to as TAB tape) transfer system, formed by bonding circuit devices or elements such as, e.g., semiconductor chips or the like to a film such as a polyimide film as a tape-like member transfer system of this type. This TAB tape transfer system is applied to a TAB handler wherein semiconductor chips mounted on the TAB tape are tested by an IC tester, namely, by a tester provided on the midway of transfer of the TAB tape.

FIGS. 7(A), 7(B) are views showing a conventional TAB tape transfer system, wherein transfer grooves 101 are formed on right and left end portions of a TAB tape 100 in the width direction of the TAB tape 100, and sprocket wheels 102 and rollers 103 are disposed on front and back surface sides of the TAB tape 100 so as to oppose each other, wherein the sprocket wheels 102 have a plurality of sprocket teeth 102a each protruded from the outer peripheries thereof and the sprocket teeth 102a are engaged in the transfer grooves 101 of the TAB tape 100 which is put between the sprocket wheels 102 and rollers 103 so as to rotatably drive the sprocket wheels 102, thereby transferring the TAB tape 100 in the direction of the arrow A.

FIGS. 8(A), 8(B) are views showing another conventional TAB tape transfer system, wherein large and small rubber roll pair 103a, 103b are disposed on the front and back surface sides of a TAB tape 100′ having no transfer grooves as explained in FIGS. 7(A), 7(B) so as to oppose each other, wherein the TAB tape 100′ is transferred in the direction of the arrow A by a frictional force generated when one rubber roll 103a is driven while it is put between the rubber roll pair 103a, 103b.

However, although there is no likelihood of the deformation or breakage of the transfer grooves 101 even if the sprocket wheels 102 are rotated at high speed provided that the TAB tape 100 has a thickness in the order of about 75 μm, there is a possibility that the TAB tape 100 is not transferred smoothly because of the deformation or breakage of the transfer grooves 101 caused by the sprocket teeth 102a if the TAB tape has a thickness in the order of 25 μm in view of the fact that a thin film tape having a thickness in the order of 25 μm has been actually manufactured recently.

In the transfer system by the rubber roll pair 103a, 103b, semiconductor chips are mounted on the TAB tape 100′ at substantially the central portion thereof, wherein when the substantially central portion on which the semiconductor chips are mounted is pressed by the rubber roll pair 103a, 103b, there is a possibility that the semiconductor chips are mechanically broken by a pressing force or pressure or the like of the rollers or they are electrically damaged by electrostatic breakage caused by static electricity that is charged on the rollers.

Whereupon, although it is conceived that roller pairs are respectively disposed on front and back surface sides of the TAB tape at right and left end portions in a width direction, there is a possibility that the rollers are deformed by the displacement of roller pairs disposed to oppose each other in the degree of parallelization or by the difference in pressing force, and the TAB tape is curved toward the center thereof or the TAB tape is come off immediately from the roller pairs when the TAB tape is transferred at high speed because the central portion of the TAB tape is not restricted.

### SUMMARY OF THE INVENTION

The invention has been developed to solve the foregoing conventional problems and it is an object of the invention to provide a tape-like member transfer system capable of transferring a thin film tape-like member while it is not bent in a width direction.

To achieve the above object, a tape-like member transfer system of a first aspect of the invention comprises a supply reel 10 around which a tape-like member 12 is wound and in which the tape-like member 12 is housed, a housing reel 20 for unwinding the tape-like member 12, and press rollers 14₁, 14₂, 16₁, 16₂ which are arranged between the supply reel 10 and the housing reel 20 so as to press both end portions of the tape-like member 12 in a width direction, wherein axes O₁, O₂ of the press rollers 14₁, 14₂, 16₁, 16₂ are arranged to be inclined at a small angle relative to a transfer direction of the tape-like member 12 so that divided forces of the press rollers act on the TAB tape 12 outward in the width direction.

The tape-like member transfer system of the second aspect of the invention is characterized in that the press rollers 14₁, 14₂, 16₁, 16₂ comprise transfer roller pairs composed of driving rollers 14₁ₐ, 14₂ₐ, 16₁ₐ, 16₂ₐ and driven rollers 14_{1b}, 14_{2b}, 16_{1b}, 16_{2b} for transferring the tape-like member 12 while putting it therebetween.

The tape-like member transfer system of the third aspect of the invention is characterized in further comprising angle change means 28 for changing an inclination angle of the axes O₁, O₂ of the press rollers 14₁, 14₂, 16₁, 16₂.

The tape-like member transfer system of the fourth aspect of the invention is characterized in further comprising detection means 30 disposed on a transfer path of the tape-like member 12 for detecting the curvature of the tape-like member 12 in the width direction.

The tape-like member transfer system of the fifth aspect of the invention is characterized in that the angle change means 28 is automatically controlled on the basis of the detection of the bending of the tape-like member 12 by the detection means 30.

The tape-like member transfer system of the sixth aspect of the invention is characterized in that the tape-like member 12 is a TAB tape having conductive patterns formed thereon repeatedly along the longitudinal direction at a given interval, and the circuit devices are mounted on the conductive patterns and tested by a testing device 22 provided on the midway of transfer of the TAB tape.

The tape-like member transfer system of the seventh aspect of the invention is characterized in that the press rollers 14₁, 14₂, 16₁, 16₂ employ conductive rubber.

The first to seventh aspects of the invention are preferably applied to a case of transfer of the tape-like member 12 such as a TAB tape employing a thin film tape which is difficult to be transferred by a sprocket and so forth, and further since axes of the press rollers are arranged to be inclined at a small angle relative to the transfer direction of the tape-like member 12 so that divided forces of the press rollers act on the TAB tape 12 outward in the width direction, whereby the tape-like member 12 can be transferred at high speed with safety while it is not bent in the width direction.

The reference numerals of the foregoing elements in the brackets are intended to refer to the drawings but not intended to limit the invention thereto.

### BRIEF DESCRITION OF THE DRAWINGS

FIG. 1 is a view showing an entire configuration of a TAB tape transfer system to which the invention is applied;

FIG. 2(A) is a plan view showing a state of transfer of the TAB tape by transfer roller pairs, and FIG. 2(B) is a perspective view of the state in FIG. 2(A);

FIG. 3(A) is a plan view showing the relation between force acting on the TAB tape when the TAB tape is transferred by the transfer roller pairs, and FIG. 3(B) is a side view showing the relation in FIG. 3(A);

FIG. 4(A) is a front view showing a normal state of transfer of the TAB tape by the transfer roller pairs, and FIG. 4(B) is a side view of the state in FIG. 4(A);

FIG. 5(A) is a view showing a state where the TAB tape is bent when the TAB tape is transferred by the transfer roller pairs, and FIG. 5(B) is a side view showing the state in FIG. 5(A);

FIG. 6(A) is a plan view showing a state where driving motors of the transfer roller pairs of the TAB tape and a control motor for setting the axes of the transfer roller pairs to be inclined, FIG. 6(B) is a side view of the state in FIG. 6(A);

FIG. 7(A) is a plan view showing a state of conventional transfer of the TAB tape by sprocket wheels, and FIG. 7(B) is a perspective view of the state in FIG. 7(A); and

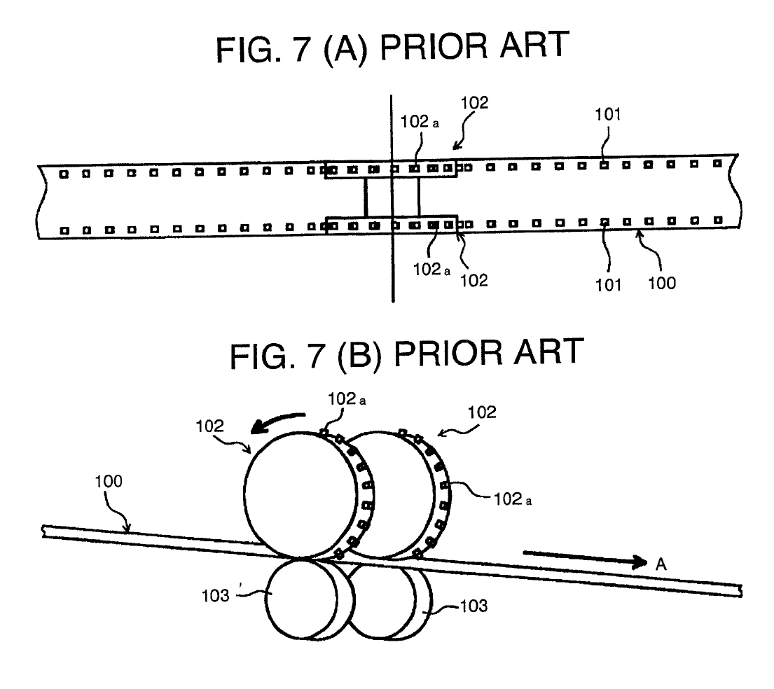

FIG. 8(A) is a plan view showing a state of another conventional transfer of the TAB tape by the transfer roller pairs, and FIG. 8(B) is a perspective view of the state in FIG. 8(A).

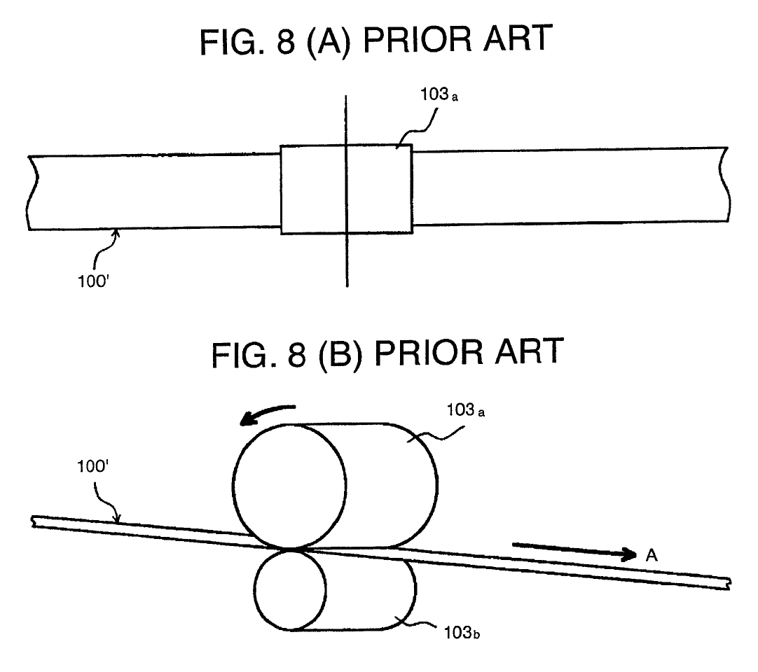

### REFERRED EMBODIMENT OF THE INVENTION

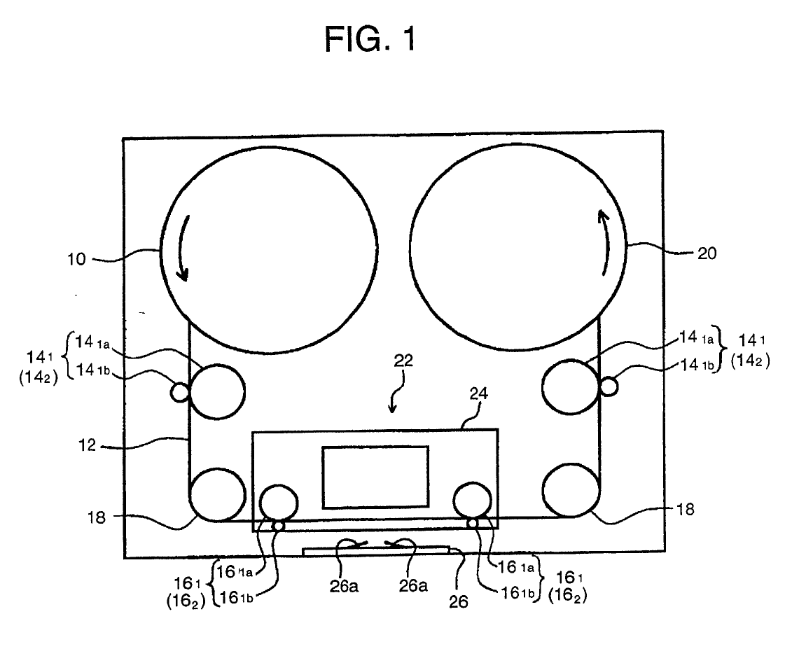

A preferred embodiment of the invention is now described with reference to FIGS. 1 to 6.

FIG. 1 is a view showing an entire configuration of a TAB tape transfer system to which the invention is applied. In the same figure, a TAB tape (tape-like member) 12 on which conductive patterns are repeatedly formed at a given interval along the longitudinal direction thereof is wound around a supply reel 10 and semiconductor chips (not shown) are mounted on the conductive patterns by means of bonding or the like. The TAB tape 12 unwound from the supply reel 10 is put between and transferred by transfer roller pairs 14₁, 14₂, 16₁, 16₂, and it is changed in direction by pinch rollers 18 and is wound around a housing reel 20.

A test device 22 is provided on the midway of transfer of the TAB tape 12, and it comprises a pusher 24, a probe card 26, and an IC tester, not shown. When one of the semiconductor chips mounted on the TAB tape 12 reaches the test device 22 at a given position, the transfer of the TAB tape 12 is temporarily stopped so that the pusher 24 presses the TAB tape 12 toward the probe card 26 together with the transfer roller pairs 16₁, 16₂ so as to allow an electrode of each semiconductor chip to electrically contact a sensor 26a of the probe card 26 so that each semiconductor chip is tested by the IC tester. The pusher 24 moves upward when the semiconductor chips are tested, and the TAB tape 12 is transferred again by the transfer roller pairs 14₁, 14₂, 16₁, 16₂.

As a result of the test, if the semiconductor chips are decided to have a good quality, they are transferred as they are and wound around the housing reel 20 while if the semiconductor chips are decided to be faulty, they are marked with a symbol showing fault or they are forcibly taken out and removed from the TAB tape 12 during the transfer thereof.

In the preferred embodiment, the axes O₁, O₂ of the transfer roller pairs (14₁, 14₂, 16₁, 16₂) are arranged to be inclined at a small angle relative to the transfer direction of the TAB tape 12 so that divided forces of the transfer roller pairs act on the TAB tape 12 outward in the width direction.

Although the TAB tape 12 is transferred by two kinds of transfer roller pairs 14₁, 14₂, 16₁, 16₂ which are respectively arranged at the right and left both end sides of the TAB tape 12 in the width direction in FIG. 1, one of transfer roller pairs, namely, transfer roller pairs 16₁, 16₂ are exemplified hereinafter because the transfer roller pairs 16₁, 16₂ are the same as the transfer roller pairs 14₁, 14₂ in function.

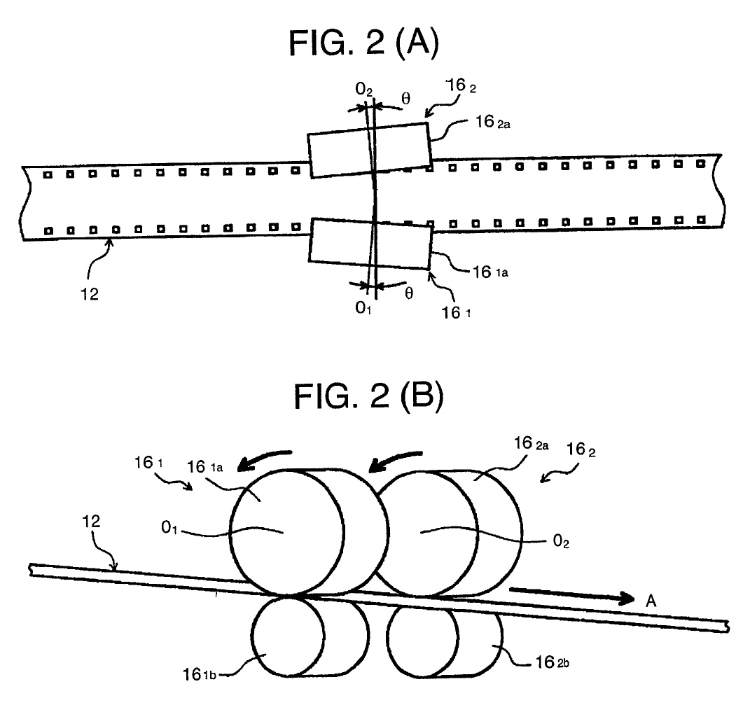

The transfer roller pair 16₁ in FIGS. 2(A) and 2(B) comprises a driving roller 16₁ₐ and a driven roller 16_{1b} which put the TAB tape 12 therebetween and are arranged to be able to be brought into intimate contact with and oppose each other, while the transfer roller pair 16₂ comprises a driving roller 16₂ₐ and driven roller 16_{2b}. These driving rollers 16₁ₐ, 16₂ₐ are paired with the driven rollers 16_{1b}, 16_{2b} and they are respectively arranged at the right and left both sides of the TAB tape 12 in a width direction to be substantially perpendicular to the transfer direction of the TAB tape 12 so as to put the TAB tape 12 therebetween. In this case, the right and left transfer roller pairs 16₁, 16₂ are arranged at the portions close to the right and left both end portions of the TAB tape 12 to an extent that they do not put the semiconductor chips mounted on the TAB tape 12 therebetween. The axes O₁, O₂ of rotation of the driving rollers 16₁ₐ, 16₂ₐ are arranged to be inclined at a small angle relative to the transfer direction so as to apply a tensile force to the TAB tape 12 in the width direction, namely, in the right and left directions (hereinafter referred to as right and left tensile forces).

In this case, the axes O₁, O₂ of rotation of the driving rollers 16₁ₐ, 16₂ₐ may be fixed by fixing means such as screws or they may have a structure to be changed in their inclination angels by variable fixing means. Further, the axes O₁, O₂ of rotation of the driving rollers 16₁ₐ, 16₂ₐ may be controlled so as to be automatically inclined relative to the transfer direction by an actuator 28, described later, on the basis of the detection of the bending of the TAB tape 12.

If the driving rollers 16₁ₐ, 16₂ₐ are synchronously rotated while they are synchronized with each other in a state where the axes O₁, O₂ of rotation of the driving rollers 16₁ₐ, 16₂ₐ are changed in angle with an axis of symmetry relative to the transfer direction of the TAB tape 12, the TAB tape 12 is transferred in the direction of the arrow A.

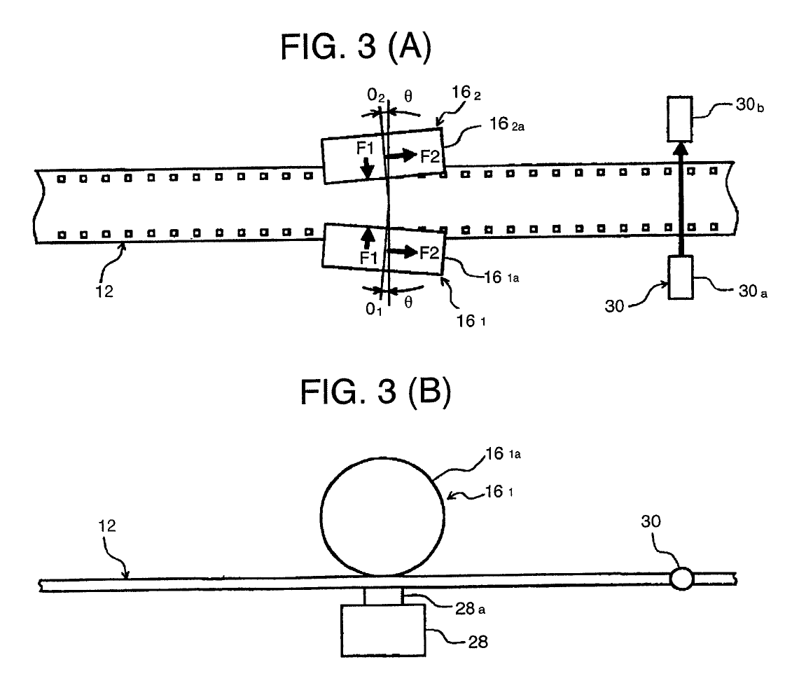

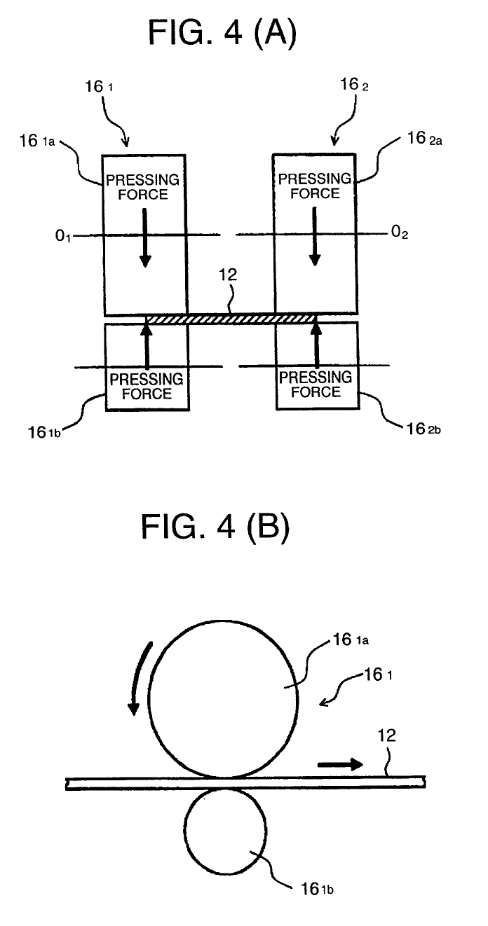

The operations of the TAB tape 12 when the axes O₁, O₂ of rotation of the driving rollers 16₁ₐ, 16₂ₐ are inclined is described with reference to FIGS. 3(A), 3(B). In FIG. 3(A), vectors F1 serving as forces for pushing the TAB tape 12 toward the center thereof and vectors F2 serving as forces (frictional forces) to urge the TAB tape 12 in the transfer direction act on the TAB tape 12 respectively. It is ideal that only the vectors F2 of the forces in the transfer direction act on the TAB tape 12 so as to smoothly transfer the TAB tape 12 as shown in FIGS. 4(A), 4(B).

However, the vectors F1 of the forces for pushing the TAB tape 12 toward the center thereof are produced in the TAB tape 12 because of deviation of circular form, dispersion in deviation from cylindrical form of the driving rollers 16₁ₐ, 16₂ₐ, and driven rollers 16_{1b}, 16_{2b} constituting the transfer roller pairs 16₁, 16₂, or because of deformation of the rollers per se caused by a pressing pressure of the tape.

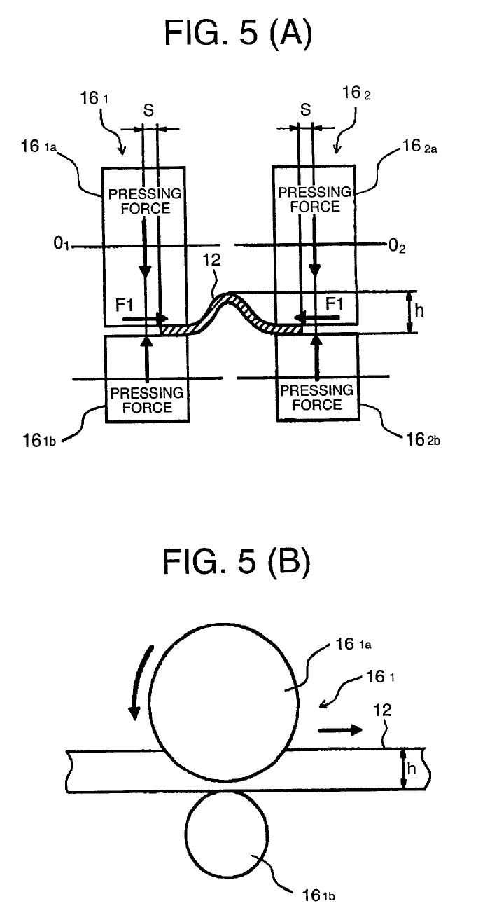

The TAB tape 12 is pressed by the driving rollers 16₁ₐ, 16₂ₐ, and driven rollers 16_{1b}, 16_{2b} against the thickness direction thereof at the right and left end portions in the width direction thereof as shown, for example, in FIGS. 5(A), 5(B), so that there are a portion where the TAB tape 12 is present between the driving rollers 16₁ₐ, 16₂ₐ, and driven rollers 16_{1b}, 16_{2b} and a portion where the TAB tape 12 is not present between the driving rollers 16₁ₐ, 16₂ₐ, and driven rollers 16_{1b}, 16_{2b}. As a result, the vectors or divided forces F1 caused by the pressing pressure by the transfer roller pairs 16₁, 16₂ are produced in the TAB tape 12 toward the central portion thereof (see FIG. 5(A)).

A bending amount s which is gradually decreased with the width direction is generated in the transferred TAB tape 12, and a curving amount h which protrudes upward in the direction substantially perpendicular to the transfer surface is produced on the central portion of the TAB tape 12.

A transmission type detection sensor 30 comprising light emitting element 30a and light receiving element 30b is employed as detection means for detecting the bending amount s of the TAB tape 12 in the width direction, and the light emitting element 30a and light receiving element 30b are arranged in the direction substantially perpendicular to the transfer surface of the TAB tape 12 and positioned and spaced up and down relative to the transfer surface of the TAB tape 12. For example, if the moving amount of the TAB tape 12 in the right and left width direction thereof when the TAB tape 12 is transferred is detected by the detection sensor 30, and the axes O₁, O₂ of rotation of the driving rollers 16₁ₐ, 16₂ₐ can be individually controlled in inclination angle in response to the detected values of the moving amount, the TAB tape 12 can be transferred without deviating from a predetermined transfer path.

According to the present embodiment, a case where the TAB tape 12 is formed of a thin film tape is conceived, and the curving amount h of the TAB tape 12 protruding upward in the direction substantially perpendicular to the transfer surface is detected instead of the detection of the bending amount s of the TAB tape 12 in the width direction (see FIG. 5). Accordingly, both the light emitting element 30a and light receiving element 30b are arranged to be spaced at the right and left end sides of the TAB tape 12 in width direction (see FIG. 3).

If the vectors F1 of the forces for pushing the TAB tape 12 toward the center thereof and the vectors F2 of the forces for urging the TAB tape 12 toward the transfer direction have the relation for satisfying the following expression, the TAB tape 12 is not curved upward at the center portion while it is bent in the width direction.

F1<F2 sin θ

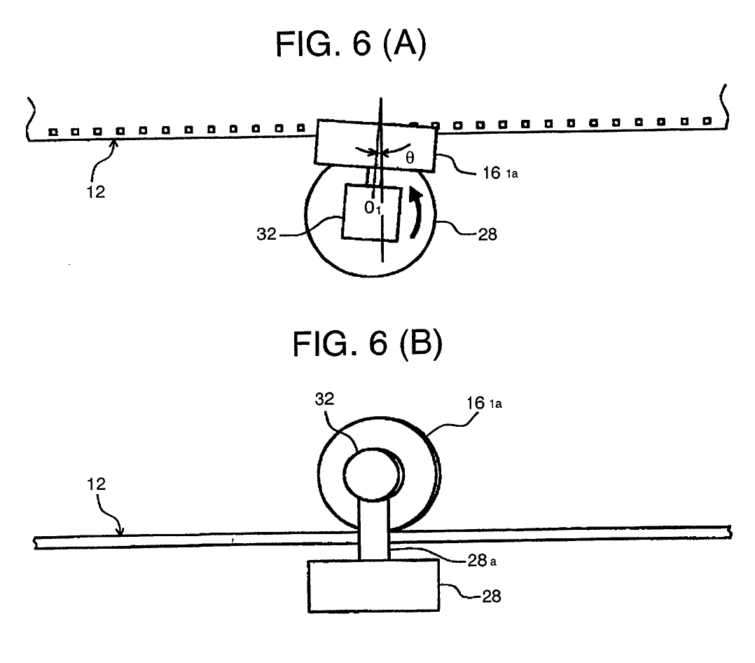

The actuator (angle changing means) 28 for inclining the axes O₁, O₂ of rotation of the driving rollers 16₁ₐ, 16₂ₐ so as to apply right and left tensile forces to the TAB tape 12 is described next with reference to FIGS. 6(A), 6(B).

Two pairs of transfer roller pairs 16₁, 16₂ which are respectively arranged at right and left both end sides of the TAB tape 12 in the width direction thereof comprise driving rollers 16₁ₐ, 16₂ₐ and driven rollers 16_{1b}, 16_{2b}. The driving rollers 16₁ₐ, 16₂ₐ are driven by driving motors 32 directly or by way of reduction gears. Further, each driving motor 32 is fixed to each control shaft 28a of each actuator 28 so that the axes O₁, O₂ of rotation of the driving rollers 16₁ₐ, 16₂ₐ formed of output shafts of the driving motors 32 are changed in angle with an axis of symmetry relative to the transfer direction of the TAB tape by the control of each actuator 28.

A control motor such as a stepping motor is employed by the actuator 28 in the preferred embodiment of the invention. If the curving amount h of the TAB tape 12 is detected by the detection sensor 30, the axes O₁, O₂ of the driving rollers 16₁ₐ, 16₂ₐ are controlled by the actuator 28 so as to be inclined in a direction to apply right and left tensile forces to the TAB tape 12.

It is a matter of course the axes O₁, O₂ of rotation of the driving rollers 16₁ₐ, 16₂ₐ can be controlled to be inclined at a given angle while the driven rollers 16_{1b}, 16_{2b} are supported by fixing shafts so as to apply a tensile force to the TAB tape 12 when the inclination angle of the driving rollers 16₁ₐ, 16₂ₐ are changed. Further, both axes of the driving and driven rollers may be changed in the same setting angle by fixing the axes O₁, O₂ of the driven rollers 16_{1b}, 16_{2b} to the control shafts 28a of the actuators 28 or supporting the axes O₁, O₂ of the driven rollers 16_{1b}, 16_{2b} by automatic aligning bearings so that the axes of rotation of the driven rollers 16_{1b}, 16_{2b} are likewise changed in angle in response to the change of the inclination angle of the axes O₁, O₂ of rotation of the driving rollers 16₁ₐ, 16₂ₐ.

The amount of control of the inclined angle in this case is in advance limited to an extent such that the TAB tape 12 is not broken when an excessive tensile force is applied to the TAB tape 12 in the left and right directions. Further, according to the preferred embodiment, although there is explained a case where the axes O₁, O₂ of rotation of the driving rollers 16₁ₐ, 16₂ₐ are controlled to be inclined in angle until the curving amount h is cancelled when the curving amount h of the TAB tape 12 is detected, it is not limited thereto, for example, the axes O₁, O₂ of rotation of the driving rollers ¹⁶₁ₐ, 16₂ₐ may be controlled to be changed in inclination amount in response to the magnitude of the curving amount h.

The driving rollers 16₁ₐ, 16₂ₐ and the driven rollers 16_{1b}, 16_{2b} constituting the transfer roller pairs 16₁, 16₂ normally employ rubber as their materials but they employ conductive rubber so as to prevent the semiconductor chips mounted on the TAB tape 12 from being electrically damaged by electrostatic breakage and they are grounded.

Although the press rollers in the preferred embodiment employ the driving rollers 16₁ₐ, 16₂ₐ and the driven rollers 16_{1b}, 16_{2b} for transferring the TAB tape 12 while putting it therebetween, the former is not limited to the latter, for example, the press rollers may be of the type employing only the driving rollers 16₁ₐ, 16₂ₐ for transferring the TAB tape 12 while pressing one surface alone of the TAB tape 12 to be transferred.

The operations of the TAB tape 12 is now described.

The transfer of the TAB tape 12 starts while the axes O₁, O₂ of rotation of the driving rollers 16₁ₐ, 16₂ₐ the transfer roller pairs 16₁, 16₂ are set to an inclination angle as set forth in FIG. 3(A), i.e. θ=0. Since the vectors F1 of the forces for pushing the tape toward the center of the TAB tape 12 in the width direction act on the TAB tape 12 as shown in FIGS. 5(A), (B) when the transfer of the TAB tape 12 starts, the central portion of the TAB tape 12 starts to curve upward. The curving amount h at this time is detected by the detection sensor 30, and the detected signal is sent to the actuator 28 by way of the controller, not shown, to drive the actuator 28 so that the inclination angles of the axes O₁, O₂ of rotation of the driving rollers 16₁ₐ, 16₂ₐ are changed substantially at the same time.

As a result, the force for urging the TAB tape 12 in the transfer direction is applied to the TAB tape 12 and the right ands left tensile forces are applied to the TAB tape 12 while the set values of the inclination angle of the axes O₁, O₂ of rotation of the driving rollers 16₁ₐ, 16₂ₐ increases until it satisfies the relation of F1<F2 sin θ, namely, until the curving amount h is not detected by the detection sensor 30. When the curving amount h is not detected, the control of the inclination angle of the axes O₁, O₂ of rotation of the driving rollers 16₁ₐ, 16₂ₐ by the actuator 28 is stopped.

As mentioned in detail above, it is possible to transfer the TAB tape stably without being curved even in the case of transfer of the thin film tape-like member by rollers not by sprockets or the like because the axes of rotation of the driving rollers which are arranged to press both end portions of the TAB tape in the width direction are arranged to be inclined at a small angle relative to the transfer direction of the TAB tape so that divided forces of the rollers act outward in the width direction. Further, even in the case of transfer of tape-like member at high speed, the tape-like member is prevented from being deviated from the transfer path.

Still further, since conductive rubber is used for the press rollers for pressing the both end portions of the tape-like member in the width direction, it is possible to efficiently prevent the circuit devices mounted on the conductive patterns of the tape-like member from being electrically damaged by electrostatic breakage.

What is claimed is:

1. A tape-like member transfer system comprising:
a supply reel on which a tape-like member is wound and in which the tape-like member is housed;
a housing reel for unwinding the tape-like member; and
press rollers which are arranged between the supply reel and the housing reel so as to press both end portions of the tape-like member in a width direction, wherein axes of the press rollers are arranged to be inclined at a small angle relative to a transfer direction of the tape-like member so that divided forces of the press rollers act on the TAB tape outward in the width direction.

2. The tape-like member transfer system according to claim 1, wherein the press rollers comprise transfer roller pairs composed of driving rollers and driven rollers for transferring the tape-like member while putting it therebetween.

3. The tape-like member transfer system according to claim 1, further comprising angle change means for changing an inclination angle of the axes of the press rollers.

4. The tape-like member transfer system according to claim 3, further comprising detection means disposed on a transfer path of the tape-like member for detecting the curvature of the tape-like member in the width direction.

5. The tape-like member transfer system according to claim 4, wherein the angle change means is automatically controlled on the basis of the detection of the curvature of the tape-like member by the detection means.

6. The tape-like member transfer system according to claims 1, 2, 3, 4 and 5, wherein the tape-like member is a TAB tape having conductive patterns formed thereon repeatedly along the longitudinal direction at a given interval, and the circuit devices are mounted on the conductive patterns and tested by a testing device provided on the midway of transfer of the TAB tape.

7. The tape-like member transfer system according to any of claims 1 to 6, wherein the press rollers employ conductive rubber.
